(19) United States
(12) Patent Application Publication
(10) Pub. No.: US 2019/0041743 A1
(43) Pub. Date: Feb. 7, 2019

(54) SUBSTRATE PROCESSING DEVICE, SUBSTRATE PROCESSING METHOD, AND PROGRAM RECORDING MEDIUM

(71) Applicant: SCREEN Holdings Co., Ltd., Kyoto (JP)

(72) Inventors: Nobuaki OKITA, Kyoto (JP); Takashi SHINOHARA, Kyoto (JP)

(21) Appl. No.: 16/076,390

(22) PCT Filed: Mar. 9, 2017
(86) PCT No.: PCT/JP2017/009518

§ 371 Date: Aug. 8, 2018

(30) Foreign Application Priority Data
Mar. 30, 2016 (JP) 2016-068582
Feb. 20, 2017 (JP) 2017-029336

(51) Int. Cl. G03F 1/82; H01L 21/304; H01L 21/67; H01L 21/673

(52) U.S. Cl. CPC G03F 1/82; H01L 21/304; H01L 21/673; H01L 21/67051; H01L 21/67046; H01L 21/67092

(57) ABSTRACT

A substrate processing apparatus includes a substrate holding rotating mechanism that holds a substrate in a horizontal posture and rotates the substrate about the vertical rotating axis passing through a principal surface of the substrate, a brush to be abutted with the principal surface of the substrate held by the substrate holding rotating mechanism to clean the principal surface of the substrate, a first nozzle that discharges a processing liquid to the principal surface of the substrate held by the substrate holding rotating mechanism, and a second nozzle that discharges the processing liquid to a downstream adjacent region adjacent to an abutment region where the brush is abutted with the principal surface of the substrate from the downstream side of the rotating direction of the substrate on the principal surface of the substrate held by the substrate holding rotating mechanism.

### TECHNICAL FIELD

The present invention relates to a substrate processing apparatus, a substrate processing method, and a program recording medium each for processing a substrate as a processing object using a processing liquid. The substrate as the processing object includes various substrates such as a semiconductor wafer, a glass substrate for a liquid crystal display device, a glass substrate for a plasma display, a substrate for a photomasks, a substrate for an optical disk, a substrate for a magnetic disk, and a substrate for a magneto-optical disk.

### BACKGROUND ART

One of the processing steps of a substrate is a step of cleaning a principal surface of the substrate. In the step of cleaning the principal surface of the substrate, a processing liquid is supplied to the principal surface of the substrate through a nozzle by which the processing liquid is to be discharged, for example. In a case where the principal surface of the substrate is insufficiently cleaned only with supply of the processing liquid, a brush cleaning step of cleaning the principal surface of the substrate with a brush is performed.

It is empirically known that in the brush cleaning step, the principal surface of the substrate is efficiently cleaned by cooperation of an action of the brush applied on dirt, etc., of the principal surface of the substrate and an action of the processing liquid applied on the dirt, etc., of the principal surface of the substrate.

The brush cleaning step can be implemented in a single substrate processing type cleaning apparatus. In the single substrate processing type cleaning apparatus, the principal surface of the substrate is cleaned with the brush in a state where the processing liquid is supplied to the principal surface of the substrate rotating in a horizontal posture. An example of the substrate processing apparatus having a structure of executing such processing is disclosed in FIG. 12 of Patent Literature 1.

### CITATION LIST

### Patent Literature

Patent Literature 1: Japanese Patent Application Publication No. 2009-123800

### SUMMARY OF THE INVENTION

### Technical Problem

In the brush cleaning step, in a periphery of the brush on the principal surface of the substrate, a region not covered with the processing liquid, or a region where a film thickness of a liquid film of the processing liquid is reduced (hereinafter, referred to as “film thickness lowering region”) may be formed.

In a case where the film thickness lowering region is formed in the periphery of the brush, dirt removed by the brush may not be discharged to an outside of the substrate but remain in the film thickness lowering region. In a case where the film thickness lowering region is formed in the periphery of the brush, a problem that particles, etc., removed by the brush adhere to the principal surface of the substrate again, etc., can be occurred.

Especially, the processing liquid flowing from a region on an upstream side of a rotating direction of the substrate is dammed by an upstream side peripheral edge of the brush. Therefore, in a region on a downstream side of the brush on the principal surface of the substrate, film thickness of the liquid film of the processing liquid is reduced. As a result, the above problem is easily occurred.

In view of the circumstances described above, it is necessary for the liquid film of the processing liquid to be maintained to have such predetermined thickness that formation of the film thickness lowering region can be suppressed on the principal surface of the substrate, especially in the periphery of the brush.

Therefore, an object of the present invention is to suppress a running out of the processing liquid or lowering of the film thickness of the liquid film of the processing liquid in the region on the downstream side of the rotating direction of the substrate with respect to the brush on the principal surface of the substrate.

### Solution to Problem

The present invention is to provide a substrate processing apparatus (1) including a substrate holding rotating mechanism (41) that holds a substrate (W) in a horizontal posture and rotates the substrate (W) about the vertical rotating axis (AX) passing through a principal surface of the substrate (W), a first nozzle (10) that discharges a processing liquid to the principal surface of the substrate (W) held by the substrate holding rotating mechanism, a brush (30) to be abutted with the principal surface of the substrate (W) held by the substrate holding rotating mechanism to clean the principal surface of the substrate (W), and a second nozzle (20) that discharges the processing liquid to a downstream adjacent region (DR) adjacent to an abutment region (AR) where the brush (30) is abutted with the principal surface of the substrate (W) from the downstream side of the rotating direction of the substrate (W) on the principal surface of the substrate (W) held by the substrate holding rotating mechanism.

The alphanumeric characters in brackets denote corresponding constituent elements, etc., in a preferred embodiment to be described later but do not intend to limit the claims to the preferred embodiment. Hereinafter, the same is applied to this section.

With this substrate apparatus (1), the processing liquid is discharged from the second nozzle (20) to the downstream adjacent region (DR). Thereby, the downstream adjacent region (DR) is replenished with the processing liquid.

Therefore, it is possible to provide the substrate processing apparatus (1) capable of suppressing reduction in a film thickness of a liquid film of the processing liquid in the downstream adjacent region (DR). With this substrate processing apparatus (1), it is possible to properly discharge dirt such as particles removed by the brush (30) by the processing liquid. Thus, it is possible to suppress dirt such as particles from adhering to the principal surface of the substrate (W) again.

The substrate processing apparatus (1) may further include a movement mechanism (60) that moves the brush (30) along the principal surface of the substrate (W) held by the substrate holding rotating mechanism.

In the substrate processing apparatus (1), the second nozzle (20) may be arranged to move integrally with the brush (30).

In the substrate processing apparatus (1), the second nozzle (20) may be arranged to discharge the processing liquid to a region (B) between the abutment region (AR) and the downstream adjacent region (DR) on the principal surface of the substrate (W).

In the substrate processing apparatus (1), a flow rate of the processing liquid discharged from the second nozzle (20) may be arranged to change according to a position of the abutment region (AR) with respect to the principal surface of the substrate (W).

With this substrate processing apparatus (1), it is possible to change the flow rate of the processing liquid discharged from the second nozzle (20) according to a size of the film thickness of the liquid film of the processing liquid along the principal surface of the substrate (W). Thereby, it is possible to properly suppress generation of the region where the film thickness of the liquid film of the processing liquid is lowered.

In the substrate processing apparatus (1), the second nozzle (20) may have a processing liquid discharge position (20A) on the central portion side of the substrate (W) with respect to the abutment region (AR) in a state where the brush (30) is abutted with a peripheral edge portion of the principal surface of the substrate (W).

In the substrate processing apparatus (1), the first nozzle (10) may be arranged to discharge the processing liquid to the central portion of the principal surface of the substrate (W).

The present invention is also to provide a substrate processing method including a substrate holding rotating step of holding a substrate (W) in a horizontal posture and rotating the substrate (W) about the vertical rotating axis (AX) passing through a principal surface of the substrate (W), a first discharging step of discharging a processing liquid from a first nozzle (10) to the principal surface of the rotating substrate (W), a brush abutting step to be executed in parallel with the first discharging step, the brush abutting step of abutting a brush (30) with the principal surface of the substrate (W), and a second discharging step to be executed in parallel with the first discharging step, the second discharging step of discharging the processing liquid from a second nozzle (20) to a downstream adjacent region (DR) adjacent to an abutment region (AR) where the brush (30) is abutted with the principal surface of the substrate (W) from the downstream side of the rotating direction of the substrate (W) on the principal surface of the substrate (W).

With this substrate processing method, the processing liquid is discharged from the second nozzle (20) to the downstream adjacent region (DR) in parallel with the first discharging step of discharging the processing liquid from the first nozzle (10) to the principal surface of the substrate (W). Thereby, the downstream adjacent region (DR) is replenished with the processing liquid.

Therefore, it is possible to provide the substrate processing method capable of suppressing reduction in a film thickness of a liquid film of the processing liquid in the downstream adjacent region (DR). With this substrate processing method, it is possible to properly discharge dirt such as particles removed by the brush (30) by the processing liquid. Thus, it is possible to suppress dirt such as particles from adhering to the principal surface of the substrate (W) again.

The substrate processing method may further include a brush moving process to be executed in parallel with the first discharging step after the brush abutting step, the brush moving step of moving the brush (30) along the principal surface of the substrate (W) in a state where the brush (30) is abutted with the principal surface of the substrate (W).

In the substrate processing method, the second discharging step may include a step to be executed in parallel with the brush moving step, the step of discharging the processing liquid from the second nozzle (20) while being moved integrally with the brush (30).

In the substrate processing method, the second discharging step may include a step of discharging the processing liquid from the second nozzle (20) to a region (B) between the abutment region (AR) and the downstream adjacent region (DR).

In the substrate processing method, the second discharging step may include a step of changing a flow rate of the processing liquid discharged from the second nozzle (20) according to a position of the abutment region (AR) with respect to the principal surface of the substrate (W).

With this substrate processing method, it is possible to change the flow rate of the processing liquid discharged from the second nozzle (20) according to a size of the film thickness of the liquid film of the processing liquid along the principal surface of the substrate (W). Thereby, it is possible to properly suppress generation of the region where the film thickness of the liquid film of the processing liquid is lowered.

In the substrate processing method, the second discharging step may include a step of discharging the processing liquid from the second nozzle (20) having a processing liquid discharge position (20A) on the central portion side of the substrate (W) with respect to the abutment region (AR) to the downstream adjacent region (DR) in a state where the brush (30) is abutted with a peripheral edge portion of the principal surface of the substrate (W).

In the substrate processing method, the first discharging step may include a step of discharging the processing liquid from the first nozzle (10) to the central portion of the principal surface of the substrate (W).

The present invention is to further provide a computer-readable program recording medium in which a program for executing a substrate processing method of cleaning a principal surface of a substrate (W) using a brush (30) is recorded, wherein the substrate processing method includes a substrate holding rotating step of holding the substrate (W) in a horizontal posture and rotating the substrate (W) about the vertical rotating axis (AX) passing through the principal surface of the substrate (W), a first discharging step of discharging a processing liquid from a first nozzle (10) to the principal surface of the rotating substrate (W), a brush abutting step to be executed in parallel with the first discharging step, the brush abutting step of abutting the brush (30) with the principal surface of the substrate (W), and a second discharging step to be executed in parallel with the first discharging step, the second discharging step of discharging the processing liquid from a second nozzle (20) to a downstream adjacent region (DR) adjacent to an abutment region (AR) where the brush (30) is abutted with the principal surface of the substrate (W) from the downstream side of the rotating direction of the substrate (W) on the principal surface of the substrate (W).

With a substrate processing method to which this program recording medium is applied, the second discharging step of discharging the processing liquid from the second nozzle (20) to the downstream adjacent region (DR) is executed in parallel with the first discharging step of discharging the processing liquid from the first nozzle (10) to the principal surface of the substrate (W). By this second discharging step, it is possible to replenish the downstream adjacent region (DR) with the processing liquid.

Therefore, it is possible to provide the computer-readable program recording medium in which the program for executing the substrate processing method capable of suppressing reduction in a film thickness of a liquid film of the processing liquid in the downstream adjacent region (DR) is recorded. With the substrate processing method using this program recording medium, it is possible to properly discharge dirt such as particles removed by the brush (30) by the processing liquid. Thus, it is possible to suppress dirt such as particles from adhering to the principal surface of the substrate (W) again.

In the program recording medium, a brush moving step to be executed in parallel with the first discharging step after the brush abutting step, the brush moving step of moving the brush (30) along the principal surface of the substrate (W) in a state where the brush (30) is abutted with the principal surface of the substrate (W) may be further included.

In the program recording medium, the second discharging step may include a step to be executed in parallel with the brush moving step, the step of discharging the processing liquid from the second nozzle (20) while being moved integrally with the brush (30).

In the program recording medium, the second discharging step may include a step of discharging the processing liquid from the second nozzle (20) to a region (B) between the abutment region (AR) and the downstream adjacent region (DR).

In the program recording medium, the second discharging step may include a step of changing a flow rate of the processing liquid discharged from the second nozzle (20) according to a position of the abutment region (AR) with respect to the principal surface of the substrate (W).

With a substrate processing method to which this program recording medium is applied, it is possible to change the flow rate of the processing liquid discharged from the second nozzle (20) according to a size of the film thickness of the liquid film of the processing liquid along the principal surface of the substrate (W). Thereby, it is possible to properly suppress generation of the region where the film thickness of the liquid film of the processing liquid is lowered.

In the program recording medium, the second discharging step may include a step of discharging the processing liquid from the second nozzle (20) having a processing liquid discharge position (20A) on the central portion side of the substrate (W) with respect to the abutment region (AR) to the downstream adjacent region (DR) in a state where the brush (30) is abutted with a peripheral edge portion of the principal surface of the substrate (W).

In the program recording medium, the first discharging step may include a step of discharging the processing liquid from the first nozzle (10) to the central portion of the principal surface of the substrate (W).

The aforementioned and other objects, features, and effects of the present invention will be clarified by the following description of a preferred embodiment with reference to the accompanying drawings.

### BRIEF DESCRIPTION OF THE DRAWINGS

FIG. 1 is a schematic view showing a configuration of a substrate processing apparatus according to a preferred embodiment of the present invention.

FIG. 2 is a schematic view showing a configuration of a processing liquid supply mechanism of the substrate processing apparatus.

FIG. 3 is a concept view for illustrating a configuration of a control mechanism of the substrate processing apparatus.

FIG. 4 is a schematic plan view for illustrating a mechanism of generation of a film thickness lowering region.

FIG. 5 is a flowchart for illustrating processing steps of a substrate by the substrate processing apparatus.

FIG. 6 is a schematic side view for illustrating an effect of replenishment of a processing liquid.

### DETAILED DESCRIPTION OF PREFERRED EMBODIMENTS

Hereinafter, a configuration and actions of a substrate processing apparatus 1 will be described in order. In the drawings, the same reference signs will be given to portions having the same configurations and the same functions, and description thereof shall be omitted below.

### Configuration of Substrate Processing Apparatus 1

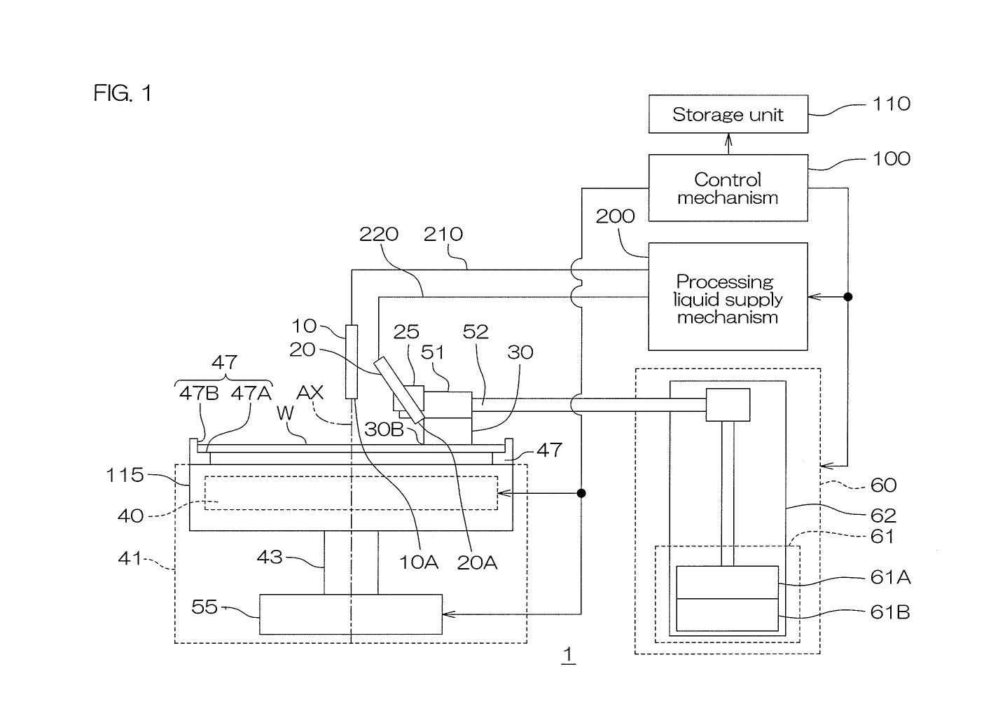

FIG. 1 is a schematic view showing the configuration of the substrate processing apparatus 1 according to a preferred embodiment of the present invention.

The substrate processing apparatus 1 is a single substrate processing type substrate processing apparatus that processes one substantially disk-shaped substrate W such as a semiconductor wafer one at a time. The substrate processing apparatus 1 includes a spin chuck 41 that holds the substrate W in a horizontal posture and rotates the substrate about a vertical rotating axis AX passing through a central portion of a principal surface of the substrate W.

The spin chuck 41 includes a spin base 115 of a substantially disk shape, a support shaft 43 of a columnar shape joined to a lower portion of the spin base 115, and a spin base rotating mechanism 55 joined to the support shaft 43. The spin base rotating mechanism 55 may include an electric motor.

Plural chuck pins 47 are arranged in a peripheral edge portion of an upper surface of the spin base 115. The plural chuck pins 47 are arranged at substantially equal intervals along the circumferential direction of the spin base 115. The plural chuck pins 47 hold the substrate W from a peripheral edge of the substrate. Each of the plural chuck pins 47 has a mounting portion 47A on which the substrate W is mounted, and an abutting portion 47B that presses against the peripheral edge of the substrate W and gives holding force to hold the substrate W.

A chuck pin movement mechanism 40 is arranged inside the spin base 115. The chuck pin movement mechanism 40 is joined to the chuck pins 47. In FIG. 1, the chuck pin movement mechanism 40 is shown by a dotted line. The chuck pin movement mechanism 40 displaces the chuck pins 47 along a radial direction of the spin base 115. Thereby, the chuck pins 47 are displaced between an open position and a close position.

The open position of the chuck pins 47 is a position where the chuck pins 47 are moved in a radially outward direction of the spin base 115 and the abutting portion 47B is separated from the peripheral edge of the substrate W. The close position of the chuck pins 47 is a position where the chuck pins 47 are moved in a radially inward direction of the spin base 115 and the abutting portion 47B is brought into contact with the peripheral edge of the substrate W.

The substrate processing apparatus 1 includes an arm movement mechanism 60 arranged in a periphery of the spin chuck 41. The arm movement mechanism 60 includes an arm 52, a movable portion 61 that is joined to the arm 52 and moves the arm 52, and a cover 62 that covers the movable portion 61. The cover 62 shields leakage of contaminants such as particles generated in the movable portion 61 to outside.

The arm 52 is formed in a substantially long axis shape having one end and the other end. One end of the arm 52 is joined to the movable portion 61 of the arm movement mechanism 60. A head 51 is joined to the other end of the arm 52. A brush 30 by which the substrate W is cleaned is attached a lower portion of the head 51. The brush 30 has a lower surface serving as an abutting portion to be abutted with the principal surface of the substrate W (which is an upper surface of the substrate W and the same is applied below). The lower surface of the brush 30 also serves as a cleaning surface by which the principal surface of the substrate W is cleaned.

As a mode of fixing the brush 30 to the head 51, various modes are available. For example, the brush 30 may be fixed to a leading end or a side surface of the head 51. The head 51 is moved by the arm movement mechanism 60 in a state where the brush 30 is fixed. Thereby, the brush 30 can be moved appropriately.

The movable portion 61 of the arm movement mechanism 60 includes an axis rotating mechanism 61A and an up-down movement mechanism 61B. The head 51 and the brush 30 are oscillated in parallel with the upper surface of the spin base 115 by the axis rotating mechanism 61A. The head 51 and the brush 30 are moved up and down with respect to the upper surface of the spin base 115 by the up-down movement mechanism 61B.

The movable portion 61 of the arm movement mechanism 60 may include a forward/rearward movement mechanism 61C (not shown) in place of or in addition to the axis rotating mechanism 61A. The head 51 and the brush 30 can be moved forward/rearward in the long axis direction of the arm 52 by the forward/rearward movement mechanism 61C.

The substrate processing apparatus 1 includes a first nozzle 10 by which a processing liquid is supplied to the principal surface of the substrate W held by the spin chuck 41, a second nozzle 20 by which a processing liquid is supplied to the principal surface of the substrate W held by the spin chuck 41, and a processing liquid supply mechanism 200 that is connected to the first nozzle 10 and the second nozzle 20.

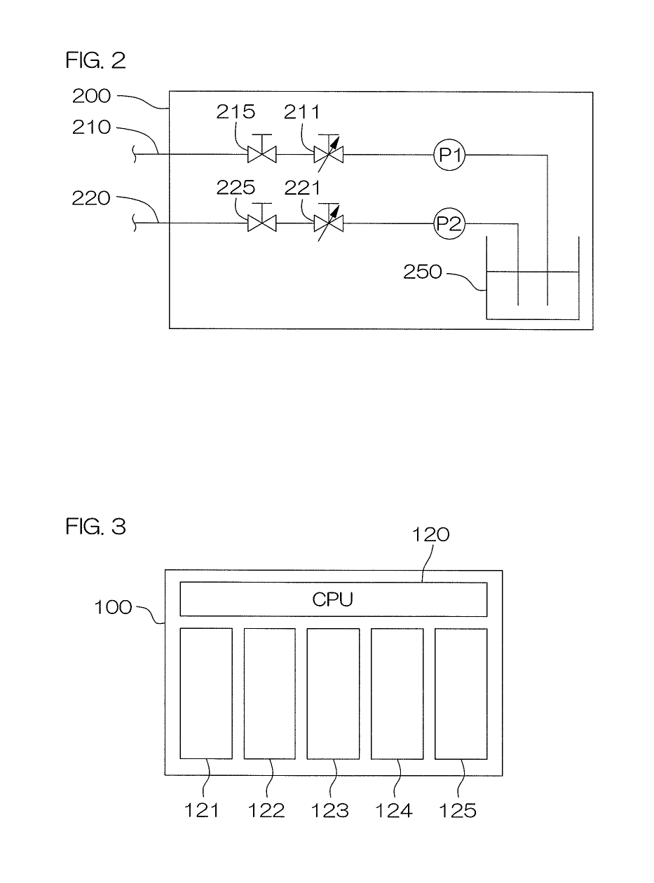

With reference to FIG. 2 in addition to FIG. 1 appropriately, arrangements and configurations of the first nozzle 10, the second nozzle 20, and the processing liquid supply mechanism 200 will be described. FIG. 2 is a schematic view showing the configuration of the processing liquid supply mechanism 200 of the substrate processing apparatus 1.

The first nozzle 10 may be fixed above the principal surface of the substrate W by a joining member (not shown) in the present preferred embodiment. The joining member (not shown) may be a fixing tool that fixes the first nozzle 10 above the principal surface of the substrate W. The first nozzle 10 discharges the processing liquid toward the central portion of the principal surface of the substrate W. The first nozzle 10 is arranged at such height that the first nozzle 10 is not in contact with the second nozzle 20 and the head 51.

The first nozzle 10 includes a discharge port 10A from which the processing liquid is discharged. The first nozzle 10 is connected to the processing liquid supply mechanism 200 through a pipe 210. The first nozzle 10 discharges the processing liquid supplied from the processing liquid supply mechanism 200 from the discharge port 10A.

More specifically, the processing liquid supply mechanism 200 supplies the processing liquid stored in a processing liquid tank 250 to the first nozzle 10 through the pipe 210 by a pump P1. An adjustment valve 211 that adjusts a flow rate of the processing liquid and an on-off valve 215 that opens/closes the pipe 210 are installed in the pipe 210.

The flow rate of the processing liquid discharged from the first nozzle 10 may be regulated by a driving output of the pump P1 and an opening degree of the adjustment valve 211. Start and stop of discharge of the processing liquid by the first nozzle 10 may be executed by opening and closing the on-off valve 215.

The arrangement and the configuration of the first nozzle 10 described above are only examples. As a configuration in which the processing liquid is discharged from the discharge port 10A of the first nozzle 10 toward the central portion of the principal surface of the substrate W, various modes can be adopted. For example, a so-called shielding plate arranged above the substrate W so as to oppose the principal surface of the substrate W may be included, and the discharge port 10A of the first nozzle 10 may be arranged in a central portion of the shielding plate.

The first nozzle 10 may have an arrangement in which the first nozzle 10 moves along the principal surface of the substrate W by combining the first nozzle 10 with various movement mechanisms. For example, the first nozzle 10 may be arranged on the rotating axis AX of the substrate W when discharging the processing liquid toward the central portion of the principal surface of the substrate W, and retracted to a retract position so as not to oppose the principal surface of the substrate W at other times.

The first nozzle 10 may include the discharge port 10A arranged in a region not above the rotating axis AX of the substrate W, and the processing liquid may be discharged obliquely toward the central portion of the principal surface of the substrate W from the discharge port 10A.

The second nozzle 20 is arranged so as to be moved integrally with the head 51 and the brush 30. The second nozzle 20 is fixed to the head 51 via a joining member 25 in the present preferred embodiment. The joining member 25 may be a fixing tool that fixes the second nozzle 20 to the head 51.

The second nozzle 20 is fixed to a side surface of the head 51 at a predetermined angle with respect to the rotating axis AX of the substrate W. The second nozzle 20 discharges the processing liquid vertically obliquely downward with respect to the principal surface of the substrate W. The angle of the second nozzle 20 with respect to the rotating axis AX of the substrate W is, for example, 45 to 80 degrees from below the rotating axis AX of the substrate W.

The second nozzle 20 includes a discharge port 20A from which the processing liquid is discharged. The discharge port 20A of the second nozzle 20 is placed on a side of the rotating axis AX of the substrate W with respect to the brush 30 when the brush 30 is abutted with a peripheral edge portion of the principal surface of the substrate W in the present preferred embodiment. The second nozzle 20 is connected to the processing liquid supply mechanism 200 through a pipe 220. The second nozzle 20 discharges the processing liquid supplied from the processing liquid supply mechanism 200 from the discharge port 20A.

More specifically, the processing liquid supply mechanism 200 supplies the processing liquid stored in the processing liquid tank 250 to the second nozzle 20 through the pipe 220 by a pump P2. An adjustment valve 221 that adjusts the flow rate of the processing liquid and an on-off valve 225 that opens/closes the pipe 220 are installed in the pipe 220.

With reference to FIG. 2, the pipe 210 and the pipe 220 may be joined to the common processing liquid tank 250 respectively independently from each other. A common pipe 230 (not shown) joined to the processing liquid tank 250 may be further included, and the pipe 210 and the pipe 220 may be joined to the processing liquid tank 250 via the common pipe 230 (not shown).

The processing liquid tank 250 may also have a processing liquid tank 250A (not shown) for the first nozzle 10 and a processing liquid tank 250B (not shown) for the second nozzle 20. In this case, the first nozzle 10 may be joined to the processing liquid tank 250A (not shown) via the pipe 210. The second nozzle 20 may be joined to the processing liquid tank 250B (not shown) via the pipe 220.

The flow rate of the processing liquid discharged from the second nozzle 20 may be regulated by a driving output of the pump P2 and an opening degree of the adjustment valve 221. Start and stop of discharge of the processing liquid by the second nozzle 20 may be executed by opening and closing the on-off valve 225.

With reference to FIG. 3 in addition to FIG. 1 appropriately, a configuration of a control mechanism. 100 will be described. FIG. 3 is a concept view for illustrating the configuration of the control mechanism 100 of the substrate processing apparatus 1.

With reference to FIGS. 1 and 3, the substrate processing apparatus 1 includes the control mechanism 100. The control mechanism 100 controls the chuck pin movement mechanism 40, the spin base rotating mechanism 55, the movable portion 61 of the arm movement mechanism 60, the pumps P1, P2 joined to the processing liquid supply mechanism 200, the adjustment valves 211, 221, the on-off valves 215, 225, etc.

The control mechanism 100 includes a CPU 120, a processing liquid supply mechanism control unit 121, an arm drive mechanism control unit 122, a chuck pin drive mechanism control unit 123, a spin base rotating mechanism control unit 124, and other control units 125. A storage unit 110 is connected to the control mechanism 100.

The processing liquid supply mechanism control unit 121 controls drive of the pumps P1, P2 joined to the processing liquid supply mechanism 200, the adjustment valves 211, 221, the on-off valves 215, 225, etc. The processing liquid supply mechanism control unit 121 may include a first nozzle control unit (not shown) that controls a side of the first nozzle 10, and a second nozzle control unit (not shown) that controls a side of the second nozzle 20.

The arm drive mechanism control unit 122 controls drive of the movable portion 61 of the arm movement mechanism 60. The chuck pin drive mechanism control unit 123 controls drive of the chuck pin movement mechanism 40. The spin base rotating mechanism control unit 124 controls drive of the spin base rotating mechanism 55.

The storage unit 110 is a recording medium that stores recipes and various algorithms. Procedures of processing steps, apparatus control parameters required for implementing the processing steps, etc., are stored in the recipes. Various algorithms are used for calculating values of the apparatus control parameters and control signals for each operator command information or each step.

Each of the above control units calculates a value of a control signal in cooperation with the storage unit 110, and transmits the control signal according to an advancing state of the processing steps of the apparatus to an access point to which each of the above control units is connected.

Although not shown, a partition wall that suppresses a splashing of the processing liquid, a contamination of the atmosphere, etc., following the processing of the substrate W may be arranged in a periphery of the spin base 115. In this case, the control mechanism 100 may be arranged outside the partition wall, that is, in a region on the opposite side of the spin base 115 with respect to the partition wall. The control mechanism 100 may perform communication with the various mechanisms through wires arranged to transmit and receive the control signals.

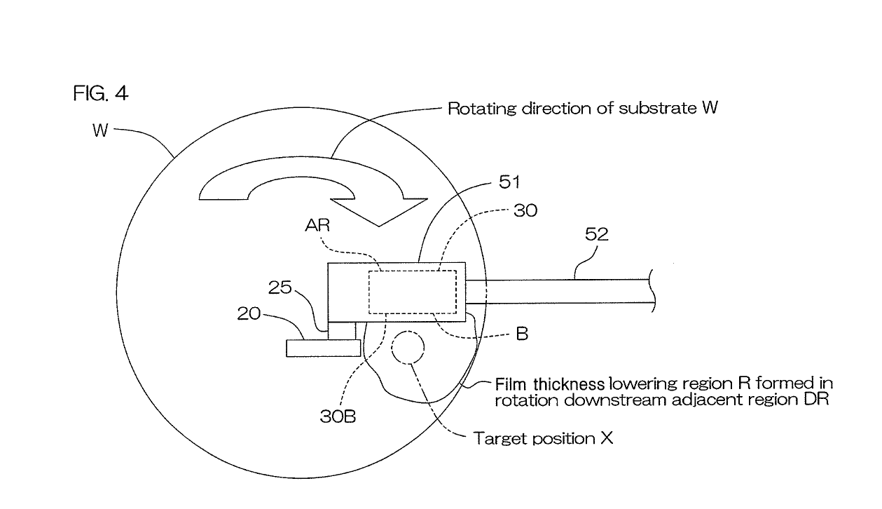

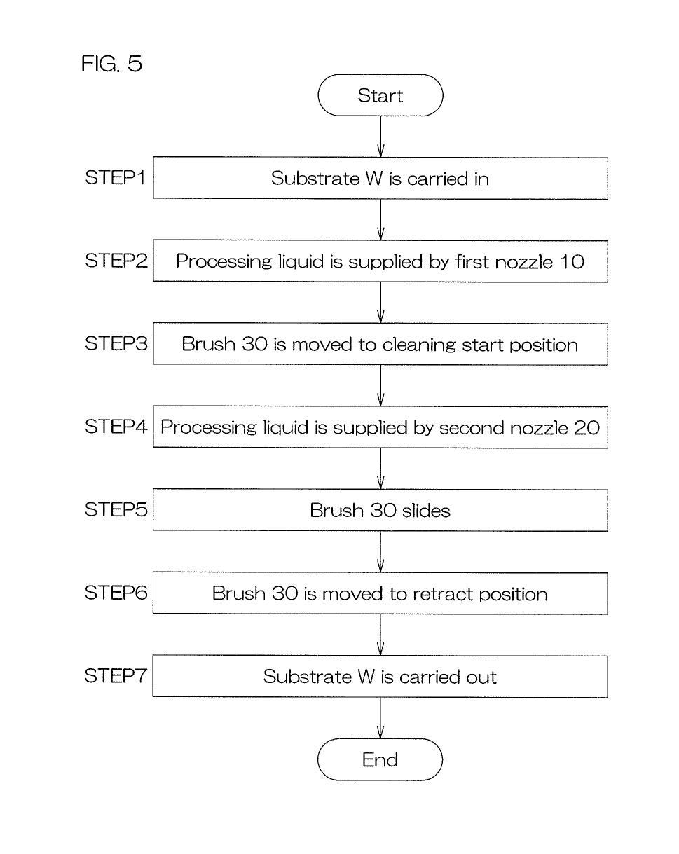

With reference to FIG. 4, a mechanism of generation of a film thickness lowering region R will be described. FIG. 4 is a schematic plan view for illustrating the mechanism of the generation of the film thickness lowering region R. In FIG. 4, for simplification, descriptions of the first nozzle 10 and the pipe 210 connected to the first nozzle 10, the pipe 220 connected to the second nozzle 20, etc., are omitted.

The film thickness lowering region R is a region where a running out of the processing liquid occurs, or a region where a film thickness of a liquid film of the processing liquid is reduced exceeding an allowable range on the principal surface of the substrate W.

Supply of the processing liquid to the principal surface of the substrate W by the second nozzle 20 is performed in a state where the processing liquid is supplied from the first nozzle 10 to the principal surface of the substrate W in a rotating state and where the brush 30 is abutted with the principal surface of the substrate W.

The processing liquid supplied from the first nozzle 10 to the principal surface of the substrate W flows from a region in the radially inward direction of the substrate W toward a region in the radially outward direction of the substrate W by centrifugal force generated by rotation of the substrate W. The region in the radially inward direction of the substrate W is also a region on a side of the central portion of the substrate W. The region in the radially outward direction of the substrate W is also a region on a side of the peripheral edge portion of the substrate W.

With reference to FIG. 4, in a region adjacent to an abutment region AR where the brush 30 is abutted with the substrate W from an upstream side of a rotating direction of the substrate W on the principal surface of the substrate W, an upstream side surface of the brush 30 opposes the rotating direction of the substrate W and a flow of the processing liquid. Therefore, the processing liquid is dammed by the upstream side surface of the brush 30.

Strictly speaking, in a state of being abutted with the principal surface of the substrate W, a lower surface of the brush 30 is not closely attached to the principal surface of the substrate W. Therefore, the processing liquid passes through a region between the lower surface of the brush 30 and the principal surface of the substrate W.

However, since a minute uneven portion or gap is formed merely between the lower surface of the brush 30 and the principal surface of the substrate W, a flow rate of the processing liquid passing through the lower surface of the brush 30 is limited. Therefore, in a region on the upstream side of the brush 30 on the principal surface of the substrate W, the film thickness of the liquid film of the processing liquid is increased in comparison to a case where the brush 30 is not abutted with the substrate W.

Meanwhile, in a predetermined region DR adjacent to the abutment region AR where the brush 30 is abutted with the substrate W from a downstream side of the rotating direction of the substrate W on the principal surface of the substrate W (hereinafter, referred to as “rotation downstream adjacent region DR”), the film thickness of the liquid film of the processing liquid is reduced in comparison to a case where the brush 30 is not abutted with the substrate W. As a result, a running out of the processing liquid occurs or the film thickness lowering region R serving as the region where the film thickness of the liquid film of the processing liquid is reduced exceeding the allowable range is formed.

That is, the film thickness lowering region R is typically generated in the rotation downstream adjacent region DR. The film thickness lowering region R is formed in a shape starting from an edge 30B on the downstream side of the rotating direction of the substrate W on an end surface (edge) of the lower surface of the brush 30 (hereinafter, referred to as “downstream side edge 30B of the brush 30”), and slightly extending from the downstream side edge 30B toward the rotation downstream adjacent region DR.

Therefore, the second nozzle 20 is preferably fixed to the head 51 such that the processing liquid is discharged from the discharge port 20A toward an arbitrary position of the rotation downstream adjacent region DR.

A target position X at which the processing liquid discharged from the second nozzle 20 lands is preferably set in the vicinity of the side surface of the brush 30 of the rotation downstream adjacent region DR on the principal surface of the substrate W. The target position X is further preferably set at a position where the processing liquid replenished by the second nozzle 20 flows to the entire region of the film thickness lowering region R.

A region of the rotation downstream adjacent region DR where the film thickness of the liquid film of the processing liquid is lowered the most is a region in the vicinity of a border line B between the abutment region AR and the rotation downstream adjacent region DR. Therefore, the processing liquid is preferably discharged from the second nozzle 20 toward the region in the vicinity of the border line B.

As described above, the second nozzle 20 according to the present preferred embodiment undertakes a role of suppressing formation of the film thickness lowering region R at a time of cleaning the principal surface of the substrate W by the brush 30. More specifically, the second nozzle 20 undertakes a role of replenishing the rotation downstream adjacent region DR adjacent to the abutment region AR with the processing liquid and suppressing the formation of the film thickness lowering region R in the rotation downstream adjacent region DR.

### Actions of Substrate Processing Apparatus 1

Next, the actions of the substrate processing apparatus 1 will be described. FIG. 5 is a flowchart for illustrating the processing steps of the substrate W by the substrate processing apparatus 1 according to the present preferred embodiment.

### STEP 1: Carry-In of Substrate W

First, the substrate W is carried in the substrate processing apparatus 1 by a substrate transfer mechanism (not shown). At this time, the chuck pins 47 are placed at the open position. After being carried in the substrate processing apparatus 1, the substrate W is mounted on the mounting portions 47A of the chuck pins 47.

After the substrate W is mounted on the mounting portions 47A, the chuck pins 47 are moved from the open position to the close position. Thereby, the peripheral edge of the substrate W is pressed by the abutting portions 47B of the chuck pins 47 and the substrate W is held by the chuck pins 47. Drive of the chuck pins 47 is controlled by the chuck pin drive mechanism control unit 123 of the control mechanism 100.

Next, the spin base rotating mechanism 55 is driven. Rotation drive force of the spin base rotating mechanism 55 is transmitted to the spin base 115 via the support shaft 43. Thereby, the substrate W is rotated together with the spin base 115. Drive of the spin base rotating mechanism 55 is controlled by the spin base rotating mechanism control unit 124 of the control mechanism 100.

### STEP 2: Supply of Processing Liquid by First Nozzle 10

Next, the processing liquid is discharged from the first nozzle 10 to the principal surface of the substrate W. This processing includes, for example, cleaning steps in the broadest scene such as removal of contaminants on the principal surface of the substrate W, and removal of residue such as a resist attached to the principal surface of the substrate W.

The processing liquid is selected depending on a purpose or a type of cleaning. A processing liquid suitable for cleaning of the substrate W by the brush 30 is preferably selected as an example of the processing liquid. For example, DIW, a mildly acidic chemical liquid, a mildly alkaline chemical liquid, etc., are used as such a processing liquid. However, depending on a type or a state of removal of dirt and residue, SC1, SC2, etc., may be used. Depending on a type or a state of resist residue, a sulfuric acid/hydrogen peroxide solution, etc., may be used.

The first nozzle 10 discharges the processing liquid toward the central portion of the principal surface of the substrate W. When the processing liquid is discharged from the first nozzle 10 to the central portion of the substrate W, the processing liquid receives the centrifugal force generated by rotation of the substrate W and spreads in the radially outward direction of the substrate W.

As one mode, the processing liquid may be discharged from the first nozzle 10 having the discharge port 10A arranged above the central portion of the principal surface of the substrate W toward the central portion of the principal surface of the substrate W. As another mode, the processing liquid may be discharged from the first nozzle 10 having the discharge port 10A arranged at a position opposing the principal surface of the substrate W in a region outside of the central portion of the principal surface of the substrate W toward the central portion of the principal surface of the substrate W. In this case, the processing liquid may be discharged from the discharge port 10A of the first nozzle 10 in a state where the processing liquid is inclined with respect to the principal surface of the substrate W such that the processing liquid lands the central portion of the substrate W.

### STEP 3: Movement of Brush 30 to Cleaning Start Position

Subsequent to or in parallel with the start of discharge of the processing liquid by the first nozzle 10, the brush 30 is moved from the retract position outside of the spin base 115 to a cleaning start position of the principal surface of the substrate W.

More specifically, first, the brush 30 is moved upward by a minute distance (about a few mm to a few cm) by the arm movement mechanism 60. The brush 30 is moved integrally with the head 51. The brush 30 is moved from the retract position to the predetermined cleaning start position on the principal surface of the substrate W by the arm movement mechanism 60. Thereby, the brush 30 is arranged at the cleaning start position of the principal surface of the substrate W.

In a case where brush cleaning is executed on the entire region of the principal surface of the substrate W, the cleaning start position by the brush 30 is in the vicinity of the central portion of the substrate W. A region in the vicinity of the central portion of the substrate W is also a region in the vicinity of a crossing position where the principal surface of the substrate W and the rotating axis AX of the substrate W cross each other.

In a case where brush cleaning is executed only on the peripheral edge portion of the substrate W, the cleaning start position by the brush 30 is a position which is the closest to the central portion of the substrate W with respect to the radial direction of the substrate W in a region of the peripheral edge portion of the substrate W where the brush cleaning is performed.

### STEP 4: Supply of Processing Liquid by Second Nozzle 20

As described above, in the rotation downstream adjacent region DR adjacent to the abutment region AR from the downstream side, there is a possibility that the film thickness lowering region R is generated (refer to FIG. 4 as well). In the film thickness lowering region R, the running out of the processing liquid occurs, or the film thickness of the liquid film of the processing liquid is reduced exceeding the allowable range. In STEP 4, by discharging the processing liquid from the second nozzle 20 toward a predetermined position, generation of the film thickness lowering region R is suppressed.

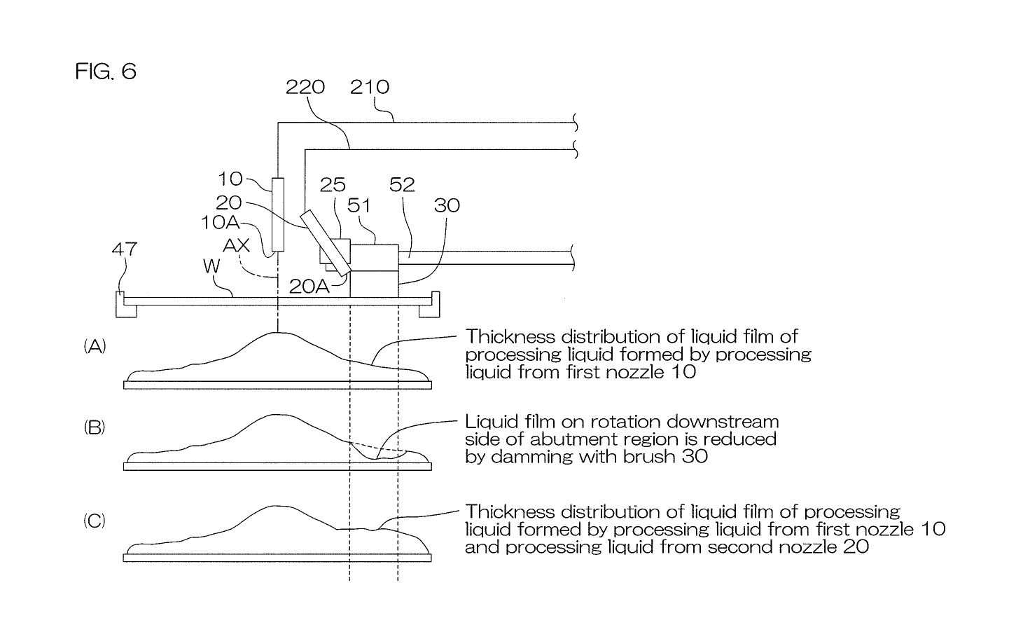

With reference to FIG. 6, an effect of replenishment of the processing liquid by the second nozzle 20 will be described. FIG. 6 is an apparatus side view for schematically illustrating the effect of replenishing the rotation downstream adjacent region DR with the processing liquid discharged by the second nozzle 20. FIG. 6 includes FIGS. 6(A) to 6(C).

FIG. 6(A) shows a film thickness distribution of the liquid film of the processing liquid supplied from the first nozzle 10 to the principal surface of the substrate Win a state where the brush 30 is separated from the principal surface of the substrate W.

FIG. 6(B) shows a film thickness distribution of the liquid film of the processing liquid supplied from the first nozzle 10 to the principal surface of the substrate Win a state where the brush 30 is abutted with the substrate W.

FIG. 6(C) shows a film thickness distribution in a state where the processing liquid is supplied from the second nozzle 20 to the film thickness lowering region R while the processing liquid is supplied from the first nozzle 10 to the principal surface of the substrate W. FIGS. 6(A) to 6(C) show the film thickness distributions on the rotation downstream adjacent region DR side on the principal surface of the substrate W.

With reference to FIG. 6(A), in STEP 4, the substrate W is rotated and the processing liquid is discharged from the first nozzle 10 toward the central portion of the principal surface of the substrate W. The discharged processing liquid flows from the region in the radially inward direction of the substrate W toward the region in the radially outward direction of the substrate W by the centrifugal force generated by rotation of the substrate W.

Operation of the centrifugal force is stronger in the region in the radially outward direction of the substrate W than in the region in the radially inward direction of the substrate W. Further, a circumferential area of the substrate W to be covered with the processing liquid is larger in the region in the radially outward direction of the substrate W than in the region in the radially inward direction of the substrate W. Therefore, the film thickness of the liquid film of the processing liquid formed in the peripheral edge portion of the substrate W tends to be smaller than the film thickness of the liquid film of the processing liquid formed in the central portion of the substrate W.

With reference to FIG. 6(B), in STEP 4, when cleaning by the brush 30 is started, dirt such as particles, etc., is removed in the abutment region AR where the brush 30 is abutted with the substrate W. The removed particles, etc., are pushed away from the radially inward direction of the substrate W to the radially outward direction of the substrate W by the processing liquid.

On the principal surface of the substrate W, in the region adjacent to the abutment region AR from the upstream side of the rotating direction of the substrate W, the upstream side surface of the brush 30 opposes the rotating direction of the substrate W and the flow of the processing liquid. Therefore, the processing liquid is dammed by the upstream side surface of the brush 30. As a result, in the region on the upstream side of the brush 30 on the principal surface of the substrate W, the film thickness of the liquid film of the processing liquid is increased in comparison to the case where the brush 30 is not abutted with the substrate W.

Meanwhile, in the rotation downstream adjacent region DR, the film thickness of the liquid film of the processing liquid is reduced in comparison to the case where the brush 30 is not abutted with the substrate W. As a result, the film thickness lowering region R is formed in the rotation downstream adjacent region DR.

With reference to FIG. 6(C), in STEP 4, in order to suppress such a problem, the processing liquid is discharged from the second nozzle 20 toward a region in the vicinity of the downstream side edge 30B of the brush 30. Thereby, in the vicinity of the downstream side edge 30B of the brush 30, the processing liquid discharged from the first nozzle 10 is replenished with the processing liquid discharged from the second nozzle 20.

Therefore, it is possible to suppress formation of the film thickness lowering region R in the vicinity of the downstream side edge 30B of the brush 30 on the principal surface of the substrate W. Thereby, as shown in FIG. 6(C), it is possible to suppress extreme lowering of the film thickness of the liquid film by replenishment of the processing liquid from the second nozzle 20.

That is, the second nozzle 20 is arranged to replenish the rotation downstream adjacent region DR with the processing liquid. Therefore, by the second nozzle 20, it is possible to replenish with the processing liquid toward an arbitrary point of the rotation downstream adjacent region DR, for example, the target position X included in the film thickness lowering region R (refer to FIG. 4). The processing liquid discharged toward the target position X (refer to FIG. 4) is discharged to the outside of the substrate W after slightly spreading in a periphery of the target position X (refer to FIG. 4).

In a case where the processing liquid does not exist in the region between the lower surface of the brush 30 and the principal surface of the substrate W, a risk increases that undesired damage is made to the principal surface of the substrate W. In the present preferred embodiment, by the processing liquid supplied from the second nozzle 20, it is also possible to replenish the region between the lower surface of the brush 30 and the principal surface of the substrate W with the processing liquid. Therefore, replenishment with the processing liquid by the second nozzle 20 is also effective for suppressing damage to the principal surface of the substrate W due to formation of the film thickness lowering region R, etc.

### STEP 5: Sliding of Brush 30

In STEP 5, in a state of being abutted with the principal surface of the substrate W, the brush 30 is moved from the cleaning start position along the radial direction of the substrate W. The brush 30 slides within a predetermined range of the substrate W. The predetermined range of the substrate W indicates a region of the substrate W where cleaning is scheduled to be performed.

In this step, the substrate W is rotated integrally with the spin base 115 in a state of being held by the chuck pins 47. In this step, the processing liquid is also discharged from the first nozzle 10 and the second nozzle 20 to the principal surface of the substrate W. In this step, the brush 30 is in sliding contact with the substrate W at the cleaning start position.

In this step, the brush 30 is moved along the radial direction of the substrate W on the principal surface of the substrate W by the arm movement mechanism 60. Thereby, the abutment region AR is moved where the brush 30 is abutted with the substrate W, and a different region of the principal surface of the substrate W is cleaned.

More specifically, since the second nozzle 20 is fixed to the head 51, the second nozzle 20 is moved integrally with the head 51 above the principal surface of the substrate W. In the present preferred embodiment, the brush 30 and the second nozzle 20 are moved along the radial direction of the substrate W integrally with the head 51 in a state where a relative positional relationship is maintained.

The second nozzle 20 replenishes the rotation downstream adjacent region DR with the processing liquid at least while the brush 30 is moved for cleaning the principal surface of the substrate W. Thereby, it is possible to suppress formation of the film thickness lowering region R in the rotation downstream adjacent region DR whose position with respect to the principal surface of the substrate W is displaced together with the brush 30.

The same actions may be realized by a preferred embodiment including a control mechanism and a drive mechanism that synchronize movement of the second nozzle 20 and movement of the head 51.

While the second nozzle 20, etc., is moved along the radial direction of the substrate W, the processing liquid is continuously discharged from the first nozzle 10 to the central portion of the principal surface of the substrate W. The flow rate of the processing liquid discharged from the first nozzle 10 is set in the recipes in advance. Information on the flow rate of the processing liquid discharged from the first nozzle 10 is stored in the storage unit 110.

The pump P1, the adjustment valve 211, and the on-off valve 215 of the processing liquid supply mechanism 200 are controlled by the processing liquid supply mechanism control unit 121 (for example, the first nozzle control unit (not shown)). The processing liquid supply mechanism control unit 121 controls the pump P1, the adjustment valve 211, and the on-off valve 215 of the processing liquid supply mechanism 200 such that the processing liquid discharged from the first nozzle 10 becomes a fixed flow rate in the steps between STEP 2 and STEP 4.

As described above, in STEP 5, even while the brush 30 and the second nozzle 20 are moved along the radial direction of the substrate W, generation of the film thickness lowering region R is suppressed.

As described with FIGS. 4 and 6, the film thickness lowering region R tends to be formed in the region in the radially outward direction of the substrate W rather than in the region in the radially inward direction of the substrate W. Therefore, in a case where the brush 30 and the second nozzle 20 are moved along the radial direction of the substrate W, the flow rate of the processing liquid discharged from the second nozzle 20 is preferably changed according to a position of the abutment region AR with respect to the radial direction of the substrate W.

More specifically, the flow rate of the processing liquid discharged from the second nozzle 20 is preferably adjusted such that the flow rate of the processing liquid when the abutment region AR (brush 30) is placed in the peripheral edge portion of the substrate W is larger than the flow rate of the processing liquid when the abutment region AR (brush 30) is placed in the central portion of the substrate W.

Information on the proper initial flow rate and control data thereof, and data of a relational expression for changing the flow rate according to the radial direction of the substrate W are stored in the storage unit 110 for each of the processing recipes of the substrate W. The flow rate according to a position of the brush 30 with respect to the principal surface of the substrate W is calculated by an arithmetic unit (not shown).

In a case where the flow rate is changed according to the radial direction of the substrate W, the flow rate L of the processing liquid discharged from the second nozzle 20 may be calculated from the following expression (1) or (2).

Flow rate L=C0×(C1+C2×D×D) (1)

Flow rate L=C0×(C1+C2×D) (2)

In the expressions (1) and (2) described above, the reference sign “D” may denote a distance between the rotation center of the substrate W and the brush 30 in a plan view (“D”≥0). In this case, a rotation center of the substrate W is zero point.

In the expressions (1) and (2) described above, the reference sign “C0” may denote, for example, a predetermined value set according to a rotation number of the substrate W (“C0”≥0). The reference sign “C0” may be set, for example, to a larger value as the rotation number of the substrate W is larger, and to a smaller value as the rotation number of the substrate W is smaller.

In the expressions (1) and (2) described above, the reference sign “C1” may denote, for example, a predetermined value set according to the thickness of the liquid film of the film thickness lowering region R formed in the rotation downstream adjacent region DR (“C1”≥0). The reference sign “C1” may be, for example, a predetermined value corresponding to the flow rate of the processing liquid with which the film thickness lowering region R is replenished.

The reference sign “C1” may also be set, for example, to a smaller value as the thickness of the liquid film formed in the film thickness lowering region R is larger, and to a larger value as the thickness of the liquid film formed in the film thickness lowering region R is smaller. As a matter of course, when a size of the brush 30 is increased, the film thickness lowering region R is also increased. Thus, the reference sign “C1” may be a predetermined value set according to the size of the brush 30.

In the expressions (1) and (2) described above, the reference sign “C2” may denote, for example, a predetermined value set according to the thickness of the liquid film of the processing liquid formed at an arbitrary position of the substrate Win a case where the film thickness lowering region R does not exist (“C2”≥0).

The reference sign “C2” may also denote, for example, a predetermined value corresponding to the flow rate of the processing liquid with which the peripheral edge portion of the substrate W is replenished in a case where the film thickness lowering region R does not exist and the thickness of the liquid film of the processing liquid formed in the peripheral edge portion of the substrate W is smaller than thickness of the liquid film of the processing liquid formed in the central portion of the substrate W.

The reference sign “C2” may also be set, for example, to a smaller value as the thickness of the liquid film of the processing liquid formed in the peripheral edge portion of the substrate W is larger, and to a larger value as the thickness of the liquid film of the processing liquid formed in the peripheral edge portion of the substrate W is smaller. Preferable values of “C0,” “C1,” and “C2” may be determined in advance, for example, through an experiment.

A value of the flow rate of the processing liquid from the second nozzle 20 according to the radial position of the brush 30 with respect to the principal surface of the substrate W may be designated for each of the recipes in a lookup table. In this case, a value which obtains a favorable processing result of low particle contamination after processing is designated as the flow rate of the processing liquid discharged from the second nozzle 20. The value which obtains a favorable processing result may be determined in advance, for example, through an experiment.

The pump P2, the adjustment valve 221, and the on-off valve 225 of the processing liquid supply mechanism 200 are controlled by the processing liquid supply mechanism control unit 121 (for example, the second nozzle control unit (not shown)). The processing liquid supply mechanism control unit 121 controls the pump P2, the adjustment valve 221, and the on-off valve 225 in the processing liquid supply mechanism 200 based on the calculated value, position information of the second nozzle 20, etc.

### STEP 6: Movement of Brush 30 to Retract Position

After cleaning by the brush 30 is finished, the brush 30 is moved to the retract position provided in the periphery of the spin base 115. More specifically, the brush 30 is moved upward from the principal surface of the substrate W by a minute distance (about a few mm to a few cm) by the arm movement mechanism 60. After that, the brush 30 is moved to the retract position.

These actions are executed by the arm drive mechanism control unit 122 controlling the arm movement mechanism 60. The arm drive mechanism control unit 122 transmits the control signal according to the recipe stored in the storage unit 110 and controls the arm movement mechanism 60.

At the same time as start of movement of the brush 30 or in parallel with movement of the brush 30, discharge of the processing liquid from the first nozzle 10 and the second nozzle 20 is stopped.

Stop of discharge of the processing liquid from the first nozzle 10 is executed by the processing liquid supply mechanism control unit 121 (first nozzle control unit (not shown)) controlling the pump P1, the adjustment valve 211, and the on-off valve 215 of the processing liquid supply mechanism 200. The processing liquid supply mechanism control unit 121 transmits the control signal according to the recipe stored in the storage unit 110 and controls the pump P1, the adjustment valve 211, and the on-off valve 215 of the processing liquid supply mechanism 200.

Stop of discharge of the processing liquid from the second nozzle 20 is executed by the processing liquid supply mechanism control unit 121 (second nozzle control unit (not shown)) controlling the pump P2, the adjustment valve 221, and the on-off valve 225 of the processing liquid supply mechanism 200. The processing liquid supply mechanism control unit 121 transmits the control signal according to the recipe stored in the storage unit 110 and controls the pump P2, the adjustment valve 221, and the on-off valve 225 of the processing liquid supply mechanism 200.

### STEP 7: Carry-Out of Substrate W

After the brush 30 is moved to the retract position, the substrate W is carried out of the substrate processing apparatus 1. In the step of carrying out the substrate W, for example, after the brush 30 is moved to the retract position, the chuck pins 47 are moved from the close position to the open position.

After the chuck pins 47 are moved to the open position, or in parallel with the action of shifting the chuck pins 47 from the close position to the open position, a hand portion of the substrate transfer mechanism (not shown) comes in a region between the spin base 115 and the substrate W.

After the chuck pins 47 are moved to the open position, the hand portion of the substrate transfer mechanism is raised. Thereby, the substrate W is lifted up by the hand portion. After that, the substrate W is carried out to the exterior of the substrate processing apparatus 1 in a state of being mounted on the hand portion of the substrate transfer mechanism. Thereby, a series of steps of cleaning the substrate W is finished.

Although the preferred embodiment of the present invention is described above, the present invention can further be implemented in other modes.

For example, as configurations of various drive mechanisms such as an arm drive mechanism, a chuck rotating mechanism, a chuck pin control mechanism, and a spinning mechanism according to the above preferred embodiment, various known modes can be adopted. Those skilled in the art can make various design changes irrespective of the configurations of the various drive mechanisms such as the arm drive mechanism, the chuck rotating mechanism, the chuck pin control mechanism, and the spinning mechanism according to the above preferred embodiment.

As a structure of the arm, a structure of the head, a structure of the spin chuck, a structure of the chuck pins, etc., according to the above preferred embodiment, various known modes can be adopted. Those skilled in the art can make various design changes irrespective of the structure of the arm, the structure of the head, the structure of the spin chuck, the structure of the chuck pins, etc., according to the above preferred embodiment.

Regarding storage of the control information for performing open/close of the chuck pins, height and horizontal movement of the head, etc., and various design changes can also be made for specific modes of control.

The present application corresponds to Japanese Patent Application No. 2016-068582 filed on Mar. 30, 2016 in the Japan Patent Office and Japanese Patent Application No. 2017-29336 filed on Feb. 20, 2017 in the Japan Patent Office, and the entire disclosure of these applications is incorporated herein by reference.

While the preferred embodiment of the present invention has been described in detail above, these are merely specific examples used to clarify the technical contents of the present invention, and the present invention should not be interpreted as being limited to these specific examples, and the scope of the present invention shall be limited only by the appended claims.

### Description of Reference Signs

1: Substrate processing apparatus
10: First nozzle
10A: Discharge port of first nozzle
20: Second nozzle
20A: Discharge port of first nozzle
25: Joining member
30: Brush
30B: Downstream side edge of brush
40: Chuck pin movement mechanism
41: Spin chuck
43: Support shaft
47: Chuck pin
47A: Mounting surface
47B: Abutting surface
51: Head
52: Arm
55: Spin base rotating mechanism
60: Arm movement mechanism
61: Movable portion
61A: Axis rotating mechanism
61B: Up-down movement mechanism
62: Cover
100: Control mechanism
110: Storage unit
115: Spin base
120: CPU
121: Processing liquid supply mechanism control unit
122: Arm drive mechanism control unit
123: Chuck pin drive mechanism control unit
124: Spin base rotating mechanism control unit
125: Control unit
200: Processing liquid supply mechanism
210: Pipe
211: Adjustment valve
215: On-off valve
220: Pipe
221: Adjustment valve
225: On-off valve
250: Processing liquid tank
AX: Rotating axis
P1: Pump
P2: Pump
R: Film thickness lowering region
W: Substrate
X: Target position

1. A substrate processing apparatus comprising:
a substrate holding rotating mechanism that holds a substrate in a horizontal posture and rotates the substrate about a vertical rotating axis passing through a principal surface of the substrate;
a first nozzle that discharges a processing liquid to the principal surface of the substrate held by the substrate holding rotating mechanism;
a brush to be abutted with the principal surface of the substrate held by the substrate holding rotating mechanism to clean the principal surface of the substrate; and
a second nozzle that discharges a processing liquid to a downstream adjacent region adjacent to an abutment region where the brush is abutted with the principal surface of the substrate from a downstream side of a rotating direction of the substrate on the principal surface of the substrate held by the substrate holding rotating mechanism.

2. The substrate processing apparatus according to claim 1, further comprising:
a movement mechanism that moves the brush along the principal surface of the substrate held by the substrate holding rotating mechanism.

3. The substrate processing apparatus according to claim 2, wherein
the second nozzle is moved integrally with the brush.

4. The substrate processing apparatus according to claim 1, wherein
the second nozzle discharges a processing liquid to a region between the abutment region and the downstream adjacent region on the principal surface of the substrate.

5. The substrate processing apparatus according to claim 1, wherein
a flow rate of a processing liquid discharged from the second nozzle is changed according to a position of the abutment region with respect to the principal surface of the substrate.

6. The substrate processing apparatus according to claim 1, wherein
the second nozzle has a processing liquid discharge position on a central portion side of the substrate with respect to the abutment region in a state where the brush is abutted with a peripheral edge portion of the principal surface of the substrate.

7. The substrate processing apparatus according claim 1, wherein
the first nozzle discharges a processing liquid to a central portion of the principal surface of the substrate.

8. A substrate processing method comprising:
a substrate holding rotating step of holding a substrate in a horizontal posture and rotating the substrate about a vertical rotating axis passing through a principal surface of the substrate;
a first discharging step of discharging a processing liquid from a first nozzle to the principal surface of the rotating substrate;
a brush abutting step to be executed in parallel with the first discharging step, the brush abutting step of abutting a brush with the principal surface of the substrate; and
a second discharging step to be executed in parallel with the first discharging step, the second discharging step of discharging a processing liquid from a second nozzle to a downstream adjacent region adjacent to an abutment region where the brush is abutted with the principal surface of the substrate from a downstream side of a rotating direction of the substrate on the principal surface of the substrate.

9. The substrate processing method according to claim 8, further comprising:
a brush moving step to be executed in parallel with the first discharging step after the brush abutting step, the brush moving step of moving the brush along the principal surface of the substrate in a state where the brush is abutted with the principal surface of the substrate.

10. The substrate processing method according to claim 9, wherein
the second discharging step includes a step to be executed in parallel with the brush moving step, the step of discharging a processing liquid from the second nozzle while being moved integrally with the brush.

11. The substrate processing method according to claim 8, wherein
the second discharging step includes a step of discharging a processing liquid from the second nozzle to a region between the abutment region and the downstream adjacent region.

12. The substrate processing method according to claim 8, wherein
the second discharging step includes a step of changing a flow rate of a processing liquid discharged from the second nozzle according to a position of the abutment region with respect to the principal surface of the substrate.

13. The substrate processing method according to claim 8, wherein
the second discharging step includes a step of discharging a processing liquid from the second nozzle having a processing liquid discharge position on a central portion side of the substrate with respect to the abutment region to the downstream adjacent region in a state where the brush is abutted with a peripheral edge portion of the principal surface of the substrate.

14. The substrate processing method according to claim 8, wherein
the first discharging step includes a step of discharging a processing liquid from the first nozzle to a central portion of the principal surface of the substrate.

15. A computer-readable program recording medium in which a program for executing a substrate processing method of cleaning a principal surface of a substrate using a brush is recorded, wherein
the substrate processing method comprises:
a substrate holding rotating step of holding a substrate in a horizontal posture and rotating the substrate about a vertical rotating axis passing through a principal surface of the substrate;
a first discharging step of discharging a processing liquid from a first nozzle to the principal surface of the rotating substrate;
a brush abutting step to be executed in parallel with the first discharging step, the brush abutting step of abutting the brush with the principal surface of the substrate; and
a second discharging step to be executed in parallel with the first discharging step, the second discharging step of discharging a processing liquid from a second nozzle to a downstream adjacent region adjacent to an abutment region where the brush is abutted with the principal surface of the substrate from a downstream side of a rotating direction of the substrate on the principal surface of the substrate.

16. The program recording medium according to claim 15, wherein
a brush moving step to be executed in parallel with the first discharging step after the brush abutting step, the brush moving step of moving the brush along the principal surface of the substrate in a state where the brush is abutted with the principal surface of the substrate is further included.

17. The program recording medium according to claim 16, wherein
the second discharging step includes a step to be executed in parallel with the brush moving step, the step of discharging a processing liquid from the second nozzle while being moved integrally with the brush.

18. The program recording medium according to claim 15, wherein
the second discharging step includes a step of discharging a processing liquid from the second nozzle to a region between the abutment region and the downstream adjacent region.

19. The program recording medium according to claim 15, wherein
the second discharging step includes a step of changing a flow rate of a processing liquid discharged from the second nozzle according to a position of the abutment region with respect to the principal surface of the substrate.

20. The program recording medium according to claim 15, wherein
the second discharging step includes a step of discharging a processing liquid from the second nozzle having a processing liquid discharge position on a central portion side of the substrate with respect to the abutment region to the downstream adjacent region in a state where the brush is abutted with a peripheral edge portion of the principal surface of the substrate.

21. The program recording medium according to claim 15, wherein
the first discharging step includes a step of discharging a processing liquid from the first nozzle to a central portion of the principal surface of the substrate.
